(19) United States
(12) Patent Application Publication
(10) Pub. No.: US 2010/0072491 A1
(43) Pub. Date: Mar. 25, 2010

(54) LED chip module

(76) Inventor: Baoliang Wang, Bladwin Park, CA (US)

Correspondence Address: DAVID AND RAYMOND PATENT FIRM, 108 N. YNEZ AVE., SUITE 128, MONTEREY PARK, CA, 91754, US

(21) Appl. No.: 12/284,658

(22) Filed: Sep. 23, 2008

(51) Int. Cl. H01L 33/00

(52) U.S. Cl. 257/88; 257/E33.001

(57) ABSTRACT

A LED chip module comprises a base board comprising a PCB circuit therein; and a LED chip mounting on the base board comprising a supporting frame comprising a case having a peripheral wall defining an inner room therein, and a plurality of pairs of pins provided at both sides of the case, wherein each pair of pins extending through the peripheral wall of both sides of the case respectively from the inner room of the case to the outside of the case connecting with the PCB circuit; and a LED circuit is disposed in the case, which comprises a plurality of LEDs and a plurality of pairs of conducting wires, wherein each pair of conducting wire have one end connecting to the both sides of a LED respectively, and has another end connecting to a pair of pins in the inner room of the case respectively.

### BACKGROUND OF THE PRESENT INVENTION

1. Field of Invention

The present invention relates to a LED chip module, and more particularly to a LED chip module comprising a LED chip having a plurality of pins extending therefrom for easily attaching to the base board of the LED chip module.

2. Description of Related Arts

LED (Light Emitting Diode) can directly and efficiently convert electric energy to optical energy, and has a lifespan as long as ten thousand to a hundred thousand hours. At the same time, LED is not fragile like conventional light bulb, and runs on very little electricity. When LEDs are aligned and packed together, a LED chip module is formed. The LED chip module can be driven by circuit to illuminate the LEDs thereof.

Conventional LEDs are disposed directly in the base board. This structure has a lot of drawbacks, such as firstly, this structure can only packed by hands, and there is no standard for the packaging procedure. Secondly, the conducting wires are exposed outside, so that they are easily broken. Furthermore, the integrated structure of LED and base board make the LED chip module impossible to repair.

As described in Chinese patent CN200420040555.0, LEDs are fixedly connected in series, and are packed on the base board by resin. The LED circuit only has one pair of conducting wires connecting to the circuit board, so that the heat produced by LEDs cannot be led out by the conducting wires. The heat can only dissipated by way of thermal conduction, so that the LED module is not good in thermal conductivity. Furthermore, this kind of LED module is complex to be manufactured.

In the US patent application, application Ser. No. 11/408,715, LEDs are disposed in a well formed in a triple laminate board. The circuit layer is on top of the triple laminate board, so that it is easily broken. The manufacturing procedure of this LED lamp is very complicated, so that it is not easy to be assembled and disassembled. The light of LEDs is reflected by a reflector in the well, so that the light direction is fixed and not flexible. Besides, the conducting wire on the base board is loose, which will affect the light emission of the LEDs. The two ends of the LED module are sealed, so that the heat formed inside the LED module is hard to be transferred. The structure can only be manually packed, and there is no standard procedure for the packaging. Furthermore, the LED is integratededly packed on the base board, which makes the LED module impossible to repair.

### SUMMARY OF THE PRESENT INVENTION

An object of the present invention is to provide a LED chip module comprising a LED chip which comprises a supporting frame and a plurality of LED packed in the supporting frame, which is simple in structure and easy to use.

Another object of the present invention is to provide a LED chip module, comprising a LED chip having a plurality of pins extending therefrom, which is easily attached to the base board of the LED chip module.

Another object of the present invention is to provide a LED chip module, which can be automatically assembled by machine under standard procedure and is very convenient to repair.

Another object of the present invention is to provide a LED chip module, wherein the LED chip has a plurality of conducting wire electrically connected with the circuit on the base board. The conducting wire can connect the LEDs either in series or in parallel, and at the same time transfer the heat produced by LEDs out the LED chip.

Another object of the present invention is to provide a LED chip module, wherein the LED chip comprises a heat transferring pad disposed in a bottom center of the case for transferring heat produced by LED circuit.

Another object of the present invention is to provide a LED chip module, wherein the LED chip comprises a supporting frame having a deep peripheral wall higher than the LEDs and conducting wires, so that they can be packed therein with fluorescence powder.

Another object of the present invention is to provide a LED chip module, comprising a base board having an upper metal layer and a lower PCB layer thereunder, so that the PCB layer can be protected without being exposed outside, and the upper metal layer can dissipate heat directly.

Accordingly, in order to accomplish the above objects, the present invention provides a LED chip module, comprising:

a base board comprising a PCB circuit therein; and

a LED chip mounting on the base board comprising:

a supporting frame comprising a case having a peripheral wall defining an inner room therein, and a plurality pairs of pins provided at both sides of the case, wherein each pair of pins extending through the peripheral wall of both sides of the case respectively from the inner room of the case to the outside of the case connecting with the PCB circuit; and

a LED circuit is disposed in the case, which comprises a plurality of LEDs and a plurality of pairs of conducting wires, wherein each pair of conducting wire have one end connecting to the both sides of a LED respectively, and has another end connecting to a pair of pins in the inner room of the case respectively.

These and other objectives, features, and advantages of the present invention will become apparent from the following detailed description, the accompanying drawings, and the appended claims.

### BRIEF DESCRIPTION OF THE DRAWINGS

FIG. 1 is a perspective view of a LED chip module according to a preferred embodiment of the present invention.

FIG. 2 is a schematic view of a PCB circuit a PCB layer of a base board of the LED chip module according to the above preferred embodiment of the present invention.

FIG. 3 is a perspective view of a LED chip of the LED chip module according to the above preferred embodiment of the present invention.

FIG. 4 is an exploded perspective view of a LED chip of the LED chip module according to the above preferred embodiment of the present invention.

FIG. 5 is a top view of a LED chip of the LED chip module according to the above preferred embodiment of the present invention.

FIG. 6 is a side view of a LED chip of the LED chip module according to the above preferred embodiment of the present invention.

FIG. 7 is a side view of a base board of the LED chip module according to the above preferred embodiment of the present invention.

FIG. 8 is a circuit diagram of the LED chip module according to the above preferred embodiment of the present invention.

### DETAILED DESCRIPTION OF THE PREFERRED EMBODIMENT

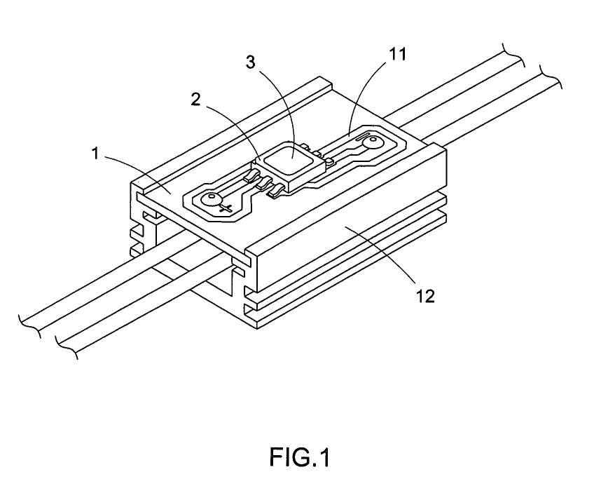

Referring to FIG. 1 of the drawings, a LED chip module according to a preferred embodiment of the present invention is illustrated, in which the LED chip module comprises a base board 1, and a LED chip mounting on the base board 1 comprising a supporting frame 2 and a LED circuit 3.

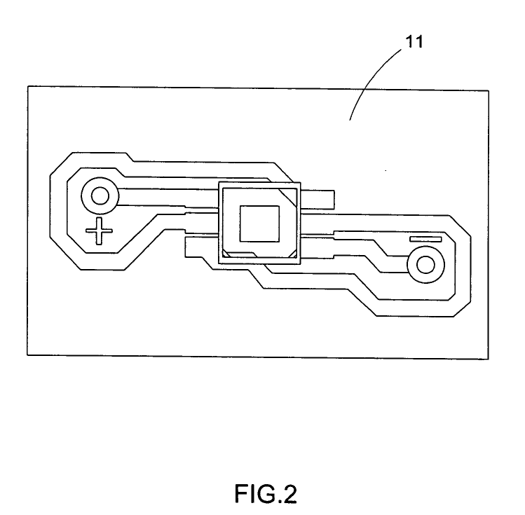

As shown in FIG. 2, the base board 1 comprises a PCB circuit 11 therein, which connects to the LED circuit 3 supported by the supporting frame 2. The base board 1 also comprises a heat radiator 12 installed under the base board 1 for radiating heat produced by the LED circuit 3.

The heat radiator 12 comprises a supporting casing having two radiating walls made of aluminum spaced apart forming an empty cavity therein for supporting the base board 1 and dissipating heat produced by LED circuit 3. The two radiating walls have two elongated retaining grooves at an inner side of two radiating walls respectively for receiving base board 1 being inserted therein. The radiating walls further comprises grooves or fins extending therefrom for enlarging the heat radiation area for enhancing the heat dissipation ability. The heat radiator 12 has opening at both sides thereof for radiating heat easily.

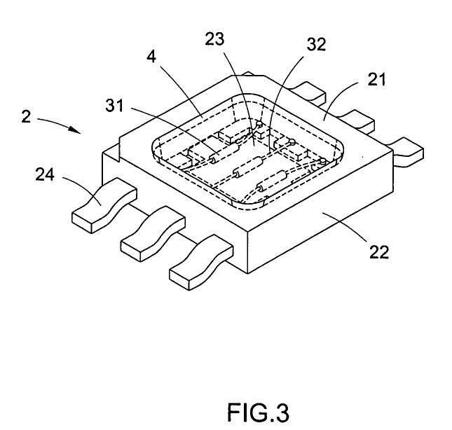

As shown in FIG. 3, the supporting frame 2 is mounted on the base board 1, comprising a case 21 having a peripheral wall 22 defining an inner room 23 therein, and a plurality of pairs of pins 24 provided at both sides of the case 21, wherein each pair of pins extends through the peripheral wall 22 of both sides of the case 21 respectively from the inner room 23 of the case 21 to the outside of the case 21. The pins 24 outside the case 21 are connected with the PCB circuit 11 respectively. The supporting frame 2 further comprises a heat transferring pad 25 disposed in a bottom center of the case 21 for transferring heat produced by LED circuit 3.

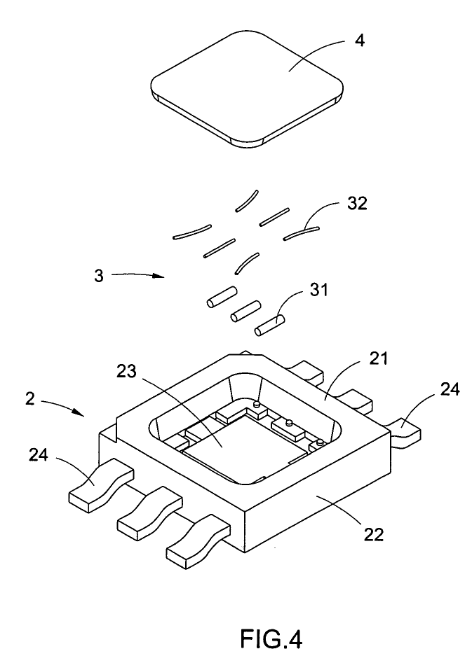

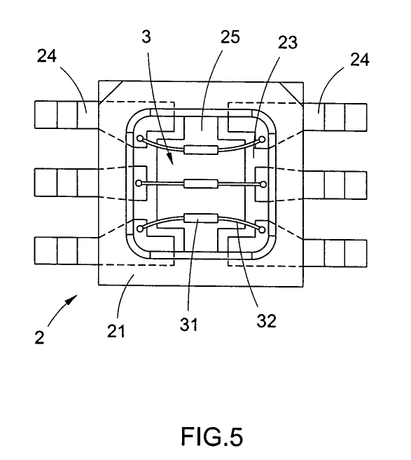

As shown in FIG. 4 and FIG. 5, LED circuit 3 is disposed in the inner room 23 of the case 21, comprising a plurality of LEDs 31 and a plurality of pairs of conducting wires 32, wherein each pair of conducting wire 32 have one end connecting to the both poles of a LED 31 respectively, and has the other end connecting to a pair of pins 24 in the inner room 23 of the case 21 respectively.

In the preferred embodiment, the case 21 of the supporting frame 2 is square shaped, having four side walls defining an inner room therein for receiving LEDs 31 therein. The four side walls are higher than the LEDs 31 and conducting wires 32 disposed therein, so as to protect the LEDs 31 and conducting wires 32 without being exposed outside.

The pin 24 is embodied as a metal plate printed on the bottom of the supporting frame 2 for electrically connecting the LEDs 31 and the PCB circuit 11 of the base board 1. In the preferred embodiment, the pin 24 is made of aluminum. Besides serving as conducting wires 32, the pins 24 can also transfer heat produced by LEDs 31 out of the LED circuit 3.

In the preferred embodiment, there are three LEDs, three pairs of conducting wires 32, and three pairs of pins 24, so that they can be connected respectively. The conducting wires 32 can also transfer the heat produced by LEDs 31 out the LED chip for enhancing the heat dissipation ability. More LEDs 31 can be arranged in the same manner, for example there are six LEDs, six pairs of conducting wires 32, and six pairs of pins 24 used in the same structure.

The LED chip module further comprises fluorescence powder 4 disposed on the LED circuit 3 in the case 21 of the supporting frame 2. Thus LEDs 31 and conducting wires 32 is buried under the fluorescence powder 4. The package procedure can be implemented automatically by machine under standard packaging procedure in the industry, and do not need to be implemented manually. LED circuit 3 is packed in the supporting frame 2, and the supporting fame 2 is weld on the base board 3, which is reliable and easy to repair.

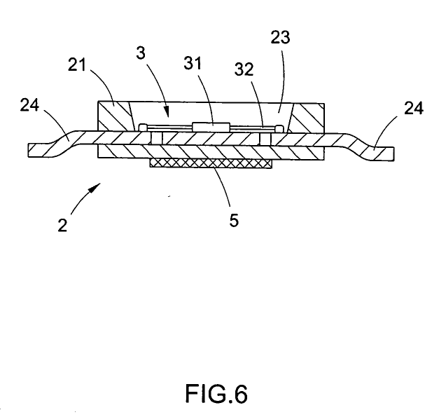

As shown in FIG. 6, LED chip module further comprise a heat dissipation cushion 5 provided between the supporting frame 2 and the base board 3 for transferring heat produced by LEDs 31 to the base board 1.

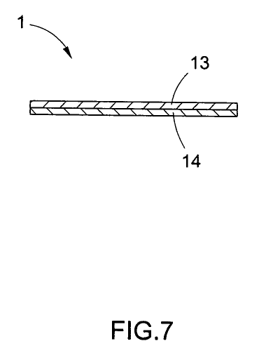

As shown in FIG. 7, the base board comprising a metal layer 13 and a PCB layer 14 mounted under the metal layer 13, wherein the PCB layer 13 has a PCB circuit 11 printed thereon. The pins 24 of the supporting frame 2 connect to the PCT circuit 11 of the PCB layer 14 by passing through the metal layer. The PCB circuit 11 is protected by being disposed under the metal layer 13 for not being easily broken. The metal layer 13 on top of the base board 1 is connected directly with the LED chip for dissipating heat well. The heat can be transferred by the heat radiator 13 under the base board quickly. The metal layer is made of aluminum in this preferred embodiment.

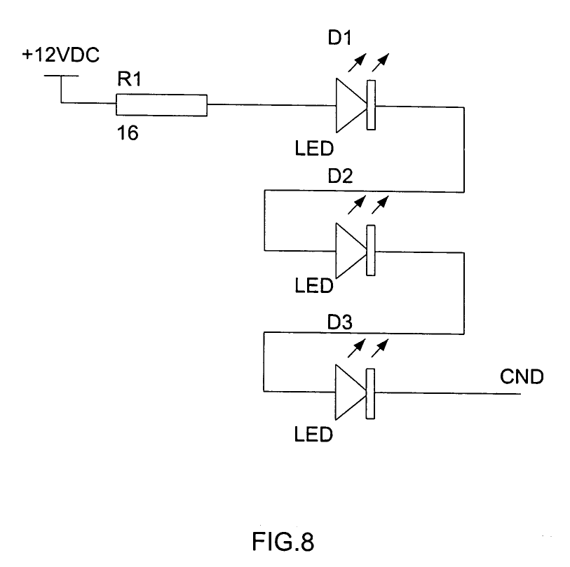

The LEDs 31 is connected to the PCB circuit 11 via pins. The PCB circuit 11 can connected the LEDs 31 in series or in parallel. As shown in FIG. 8, in the preferred embodiment, the LEDs are connected in series when connecting to the PCB circuit 11.

Accordingly, compare the LED chip module of present invention to the conventional art as disclosed in the US patent application, application Ser. No. 11/408,715, the present invention has the following improved advantages:

(1). Heat Dissipation:

The LED chip module of present invention has two openings provided at two ends of the module and further has the heat transferring pad, so that it is beneficial to transfer the heat generated from the LED chip module. Relatively, the conventional module has two sealed ends that limit the heat transfer, and without the heat transferring pad, the heat produced from the LED circuit can be barely transferred out of the module.

(2). Strong Illuminance:

The LED chip module of present invention has the strong average illuminance of 5000 lux. Relatively, the conventional module only has the average illuminance of 3500 lux.

(3). Simplified Packing Procedure:

The LED chip module of present invention can be automatically assembled by machine under stander procedure to simply the manufacture process. Relatively, the conventional module is manually packed and without stander procedure to synchronize the producing process, so that the previous module is difficult to produce.

(4). Protect the Conducting Wires from Exposing:

The conducting wires of LED chip module of present invention are automatically packed therein with fluorescence powder. Relatively, the wires of the conventional module are exposed, so that is easily to be broken.

(5). Structure for Convenient Repair:

The LEDs of the LED chip module are packed into the supporting frame mounted on the base board, which is simple in structure. Relatively, the LED of conventional module is intergradedly packed in the base board which is impossible to repair.

Therefore, according to the above points, the LED chip module of present invention has substantially improved the drawbacks of the prior art.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A LED chip, comprising:
a supporting frame comprising a case having a peripheral wall defining an inner room therein, and a plurality of pairs of pins provided at both sides of said case, wherein each pair of pins extending through said peripheral wall of both sides of said case respectively from said inner room of said case to outside said case; and
a LED circuit is disposed in said case, which comprises a plurality of LEDs and a plurality of pairs of conducting wires, wherein each pair of conducting wire have one end connecting to both sides of said one LED respectively, and has the other end connecting to said one pair of pins in said inner room of said case respectively.

2. The LED chip as recited in claim 1, wherein said peripheral walls are higher than said LEDs and conducting wires disposed therein for packing said LEDs and conducting wires therein.

3. The LED chip as recited in claim 2, wherein said peripheral wall is four side walls defining a square shaped inner room.

4. The LED chip as recited in claim 3, further comprising fluorescence powder disposed and packed on said LED circuit in said case of said supporting frame.

5. The LED chip as recited in claim 4, wherein said pins are metal plate printed on bottom of said. supporting frame for electrically connecting said LEDs and said PCB circuit of said base board.

6. The LED chip as recited in claim 5, wherein said supporting frame further comprises a heat transferring pad disposed in a bottom center of said case for transferring heat produced by said LED circuit.

7. The LED chip as recited in claim 5, further comprising a heat dissipation cushion provided beneath said supporting frame for transferring heat produced by LEDs.

8. A LED chip module, comprising:
a base board comprising a PCB circuit therein; and
a LED chip mounting on said base board comprising:
a supporting frame comprising a case having a peripheral wall defining an inner room therein, and a plurality of pairs of pins provided at both sides of said case, wherein each pair of pins extending through said peripheral wall of both sides of said case respectively from said inner room of said case to outside said case connecting with said PCB circuit; and
a LED circuit is disposed in said case, which comprises a plurality of LEDs and a plurality of pairs of conducting wires, wherein each pair of conducting wire have one end connecting to both sides of said one LED respectively, and has the other end connecting to said one pair of pins in said inner room of said case respectively.

9. The LED chip module, as recited in claim 8, wherein said peripheral wall is four side walls defining a square shaped inner room, and said peripheral walls are higher than said LEDs and conducting wires disposed therein for packing said LEDs and conducting wires therein.

10. The LED chip module, as recited in claim 9, further comprising fluorescence powder disposed and packed on said LED circuit in said case of said supporting frame.

11. The LED chip module, as recited in claim 10, wherein said pins are metal plate printed on bottom of said supporting frame for electrically connecting said LEDs and said PCB circuit of said base board.

12. The LED chip module, as recited in claim 11, wherein said supporting frame further comprises a heat transferring pad disposed in a bottom center of said case for transferring heat produced by said LED circuit.

13. The LED chip module, as recited in claim 12, further comprising a heat dissipation cushion provided between said supporting frames and said base board for transferring heat produced by LEDs to said base board.

14. The LED chip module, as recited in claim 13, wherein said supporting frame is weld on said base board, which is reliable and easy to repair.

15. The LED chip module, as recited in claim 14, wherein said base board comprises a metal layer and a PCB layer mounted under the metal layer, wherein the PCB layer has a PCB circuit printed thereon.

16. The LED chip module, as recited in claim 15, wherein said metal layer is made of aluminum.

17. The LED chip module, as recited in claim 16, wherein said base board further comprises a heat radiator installed under said base board for radiating heat produced by said LED circuit.

18. The LED chip module, as recited in claim 17, wherein said heat radiator has two radiating walls spaced apart having two elongated retaining grooves at an inner side of two radiating walls respectively for receiving base board being inserted therein for supporting the base board and dissipating heat produced by said LED circuit.

19. The LED chip module, as recited in claim 18, wherein said heat radiator has opening between said two radiating walls at both sides thereof for radiating heat easily.

20. The LED chip module, as recited in claim 18, wherein said LEDs are connected in series when connecting to said PCB circuit.
